(19) United States
(12) Patent Application Publication
(10) Pub. No.: US 2025/0214786 A1
(43) Pub. Date: Jul. 3, 2025

(54) SUBSTRATE TRANSFER EQUIPMENT AND SUBSTRATE PROCESSING SYSTEM USING THE SAME

(71) Applicant: SEMES CO., LTD., Cheonan-si (KR)

(72) Inventors: Ha Neul YOO, Anyang-si (KR); Jae Hun JEONG, Cheonan-si (KR); Cheol Yong SHIN, Yongin-si (KR); Doo Hyun BAEK, Hwaseong-si (KR)

(73) Assignee: SEMES CO., LTD., Cheonan-si (KR)

(21) Appl. No.: 19/004,660

(22) Filed: Dec. 30, 2024

(30) Foreign Application Priority Data
Dec. 29, 2023 (KR) 10-2023-0196064

(51) Int. Cl. B65G 47/90; H01L 21/677; H01L 21/687

(52) U.S. Cl. CPC B65G 47/90; H01L 21/67712; H01L 21/68707

(57) ABSTRACT

The present invention provides substrate transfer equipment. In an embodiment, the substrate transfer equipment includes: a transfer robot supporting the substrate; and a vertical actuating unit moving the transfer robot in an up-down direction, wherein the vertical actuating unit includes: a vertical frame having a slit formed with a longitudinal direction thereof provided in the up-down direction, and having a vertical space formed therein; an exhaust duct having an exhaust space connected with the vertical space and provided on a side of the vertical frame; and an actuating member positioned in the vertical space and moving a supporting unit in the up-down direction, wherein the exhaust duct is provided such that a first side is open toward the vertical space.

### CROSS-REFERENCE TO RELATED APPLICATIONS

This application claims priority to and the benefit of Korean Patent Application No. 10-2023-0196064 filed in the Korean Intellectual Property Office on Dec. 29, 2023, the entire contents of which are incorporated herein by reference.

### TECHNICAL FIELD

The present invention relates to substrate transfer equipment that conveys substrates.

### BACKGROUND ART

In the semiconductor manufacturing process, the photolithography process is a process of forming a desired resist pattern by applying a resist solution onto a substrate and exposing and developing it using a photomask. Such a photolithography process includes processes of resist solution application, exposure, and development. Further, a substrate conveying apparatus conveys substrates to processing units (or processing chambers) for performing processes, respectively.

Such a substrate processing apparatus produces particles while operating, and the produced particles are discharged to the surrounding with airflow. Such particles enter a substrate transfer passage and processing chambers, thereby causing process defects and reducing the yield.

### SUMMARY OF THE INVENTION

An objective of the present invention is to provide substrate transfer equipment that can maintain a transfer passage of substrates in a clean atmosphere, and a substrate processing system using the substrate transfer equipment.

An objective of the present invention is to provide substrate transfer equipment that can efficiently exhaust by enabling smooth movement of particles produced at a transfer robot, and a substrate processing system using the substrate transfer equipment.

Objectives of the present invention are not limited to the objectives described above. Other objectives not stated here may be clearly understood to those skilled in the art from the following description.

According to an aspect of the present invention, there may be provided substrate transfer equipment including: a transfer robot supporting the substrate; and a vertical actuating unit moving the transfer robot in an up-down direction, wherein the vertical actuating unit includes: a vertical frame having a slit formed with a longitudinal direction thereof provided in the up-down direction, and having a vertical space formed therein; an exhaust duct having an exhaust space connected with the vertical space and provided on a side of the vertical frame; and an actuating member positioned in the vertical space and moving a supporting unit in the up-down direction, wherein the exhaust duct is provided such that a first side is open toward the vertical space.

Further, the transfer robot may include: a robot body having handles supporting the substrate; a base supporting the robot body, having a Z-axial actuating unit rotating the robot body about a vertical axis, and having a first exhaust passage for discharging particles produced in a process of actuating the robot body to the outside; and a mover connected to a first end of the base, coupled to the actuating member through the slit, and having a second exhaust passage connected with the first exhaust passage.

Further, the base may further include a first exhaust fan installed in the first exhaust passage to generate airflow moving from the first exhaust passage to the second exhaust passage.

Further, the mover may be configured such that an outlet of the second exhaust passage faces a second side that is opposite to the open first side of the exhaust duct.

Further, the mover may further include a momentum reduction member provided to reduce momentum of particles that are discharged through the outlet of the second exhaust passage.

The momentum reduction member may include a porous member or a porous member or a perforated plate.

Further, the vertical frame may further include an airflow block member preventing airflow, which is exhausted through the second exhaust passage and collides with the second side of the exhaust duct, from leaking to the outside through the slit.

Further, the airflow block member may include a projection protruding from an inner surface of the vertical frame.

Further, the exhaust duct may further include a second exhaust fan exhausting airflow in the exhaust space to the outside.

According to another aspect of the present invention, there may be provided the substrate processing apparatus including: a process chamber processing the substrate; and a transfer chamber provided adjacent to the process chamber and having substrate transfer equipment transferring the substrate to the process chamber, wherein the transfer chamber includes: a transfer robot supporting a substrate; and a pair of vertical actuating units configured to horizontally move along a guide rail, supporting the transfer robot on both sides, and moving the transfer robot in an up-down direction, wherein the vertical actuating unit includes: a vertical frame having a slit formed with a longitudinal direction thereof provided in the up-down direction, and having a vertical space formed therein; an exhaust duct having an exhaust space connected with the vertical space and provided on a side of the vertical frame; and an actuating member positioned in the vertical space and moving a supporting unit in the up-down direction, wherein the exhaust duct is provided such that a first side is open toward the vertical space.

Further, the transfer robot may include: a robot body having handles supporting the substrate; a base supporting the robot body, having a Z-axial actuating unit rotating the robot body about a vertical axis, and having a first exhaust passage for discharging particles produced in a process of actuating the robot body to the outside; and a mover connected to a first end of the base, coupled to the actuating member through the slit, and having a second exhaust passage connected with the first exhaust passage.

Further, the base may further include a first exhaust fan installed in the first exhaust passage to generate airflow moving from the first exhaust passage to the second exhaust passage.

Further, the mover may be configured such that an outlet of the second exhaust passage faces a second side that is opposite to the open first side of the exhaust duct.

Further, the mover may further include a momentum reduction member provided to reduce momentum of particles that are discharged through the outlet of the second exhaust passage.

The momentum reduction member may include a porous member or a porous member or a perforated plate.

Further, the vertical frame may further include an airflow block member preventing airflow, which is exhausted through the second exhaust passage and collides with the second side of the exhaust duct, from leaking to the outside through the slit.

Further, the airflow block member may include a projection protruding from an inner surface of the vertical frame.

Further, the exhaust duct may further include a second exhaust fan exhausting airflow in the exhaust space to the outside.

According to another aspect of the present invention, there may be provided substrate transfer equipment including: a transfer robot supporting the substrate; and a vertical actuating unit moving the transfer robot in an up-down direction, wherein the vertical actuating unit includes: a vertical frame having a slit formed with a longitudinal direction thereof provided in the up-down direction, and having a vertical space formed therein; an exhaust duct having an exhaust space connected with the vertical space, provided on a side of the vertical frame, and being open on a first side being in contact with the vertical space; and an actuating member positioned in the vertical space and moving a supporting unit in the up-down direction, wherein the transfer robot includes: a robot body having handles supporting a substrate; a base supporting the robot body, having a Z-axial actuating unit rotating the robot body about a vertical axis, and having a first exhaust passage for discharging particles produced in a process of actuating the robot body to the outside; a mover connected to a first end of the base, coupled to the actuating member through the slit, and having a second exhaust passage connected with the first exhaust passage; and a first exhaust fan installed in the first exhaust passage and providing airflow moving from the first exhaust passage to the second exhaust passage, wherein the mover is configured such that an outlet of the second exhaust passage faces a second side that is opposite to the open first side of the exhaust duct, and includes a momentum reduction member provided to reduce momentum of particles that are discharged through the outlet of the second exhaust passage, wherein the vertical frame includes an airflow block member preventing airflow, which is exhausted through the second exhaust passage and collides with the second side of the exhaust duct, from leaking to the outside through the slit.

Further, the momentum reduction member may include a porous member or a perforated plate, the airflow block member may include a projection protruding from an inner surface of the vertical frame, and the exhaust duct may further include a second exhaust fan exhausting airflow in the exhaust space to the outside.

According to an embodiment of the present invention, it is possible to maintain a transfer passage of substrates in a clean atmosphere.

According to an embodiment of the present invention, it is possible to efficiently exhaust by enabling smooth movement of particles produced at a transfer robot.

The effects of the present invention are not limited to the effects described above. Effects not stated above will be clearly understood to those skilled in the art from the specification and the accompanying drawings.

### BRIEF DESCRIPTION OF THE DRAWINGS

FIG. 1 shows substrate processing equipment according to an embodiment of the present invention.

FIG. 2 is a perspective view showing an example of the substrate processing equipment of FIG. 1.

FIG. 3 is a front view of the substrate processing equipment shown in FIG. 2.

FIG. 4 is an enlarged view showing main parts of a vertical frame and an exhaust duct.

FIG. 5 is a horizontal cross-sectional view illustrating the inside of the vertical frame.

FIG. 6 and FIG. 7 are views illustrating the mover shown in FIG. 5.

FIG. 8 is a perspective view showing the exhaust duct.

FIG. 9 is a view illustrating a modified example of the mover.

### DETAILED DESCRIPTION

The advantages and features of the present invention, and methods of achieving them will be clear by referring to the exemplary embodiments that will be describe hereafter in detail with reference to the accompanying drawings. However, the present invention is not limited to the exemplary embodiments described hereafter and may be implemented in various ways, and the exemplary embodiments are provided to complete the description of the present invention and let those skilled in the art completely know the scope of the present invention and the present invention is defined by claims.

If not defined, all of terms (including technical or scientific terms) used herein have the same meanings as those that are generally received by general technologies in the field. Terms defined by general dictionaries may be construed as having the same meanings as those in the related technologies and the specification, and even if not explicitly defined here, they will not be conceptualized or excessively construed. The terms used herein are provided to describe embodiments without limiting the present invention.

In the specification, a singular form includes a plural form unless specifically stated in the sentences. The term “comprise” used in the specification and/or its various forms, such as “comprising”, “comprised”, etc. do not exclude the presence or addition of one or more other compositions, components, elements, steps, operations, and/or devices. Further, terms “provide, “have”, etc. also should be construed in the same way.

The system of this embodiment is described as being used to perform a photolithography process for substrates such as semiconductor wafers or flat panel displays, but this is only for the convenience of description and the present invention can also be used for other apparatuses including a robot for conveying substrates to processing the substrates.

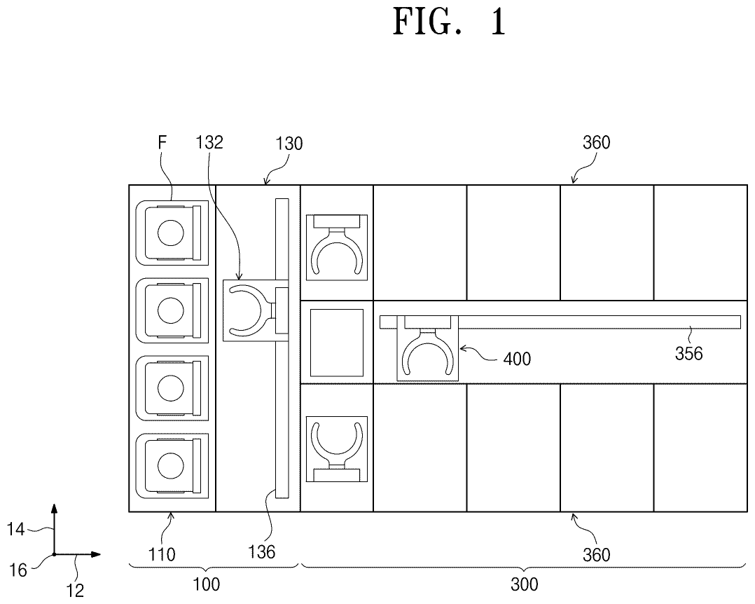

Hereafter, embodiments of the present invention are described with reference to FIG. 1 to FIG. 9.

FIG. 1 shows substrate processing equipment according to an embodiment of the present invention.

Referring to FIG. 1, a substrate processing apparatus 10 according to an embodiment of the present invention may include an index module 100 and a processing module 300.

According to an embodiment, the index module 100 and the processing module 300 may be disposed sequentially in a line. Hereafter, the direction in which the index module 100 and the processing module 300 are arranged is referred to as a first direction 12, a direction perpendicular to the first direction 12 when seen from above is referred to as a second direction 14, and a direction perpendicular to both of the first direction 12 and the second direction 14 is defined as a third direction 16.

The index module 100 transfers substrates W to the processing module 300 from containers F accommodating the substrates W and puts the substrates W processed at the processing module 300 into the containers F. The longitudinal direction of the index module 100 is provided in the second direction 14. The index module 100 has a load port 110 and an index frame 130. The load port 110 is positioned at the opposite side to the processing module 300 with the index frame 130 therebetween. The containers F accommodating substrates W are placed in the load port 110. A plurality of load ports 110 may be provided and the plurality of load ports 110 may be disposed in the second direction 14.

The container F may be a container F for sealing such as a Front Open Unified Pod (FOUP). The container F may be placed onto the load port 110 by a worker or a conveying device (not shown) such as an overhead transfer, an overhead conveyor, or an automatic guided vehicle.

An index robot 132 is provided in the index frame 130. A guide rail 136 of which the longitudinal direction is provided in the second direction 14 is provided in the index frame 14 and the index robot 132 may be provided to be movable on the guide rail 136. The index robot 132 includes a hand on which substrates W are placed and the hand may be provided to be able to move forward and backward, rotate around the third direction 16, and move in the third direction 16.

The processing module 300 can perform a predetermined process on substrates W. The processing module 300 can receive a substrate W accommodated in the container F and perform a substrate processing process. The processing module 300 has a processing chamber 360 and a transfer chamber 350. A plurality of processing chambers 360 is provided and they may be provided to be stacked on each other.

The longitudinal direction of the transfer chamber 350 is provided in parallel with the first direction 12. Substrate transfer equipment 400 is provided in the transfer chamber 350. The substrate transfer equipment 400 transfers substrates between the processing chambers 360. According to an embodiment, the substrate transfer equipment 400 includes a hand on which substrates W are placed and the hand may be provided to be able to move forward and backward, rotate around the third direction 16, and move in the third direction 16. A guide rail 356 of which the longitudinal direction is in parallel with the first direction 12 is provided in the transfer chamber 350 and the substrate transfer equipment 400 can be provided to be horizontally movable on the rail 356.

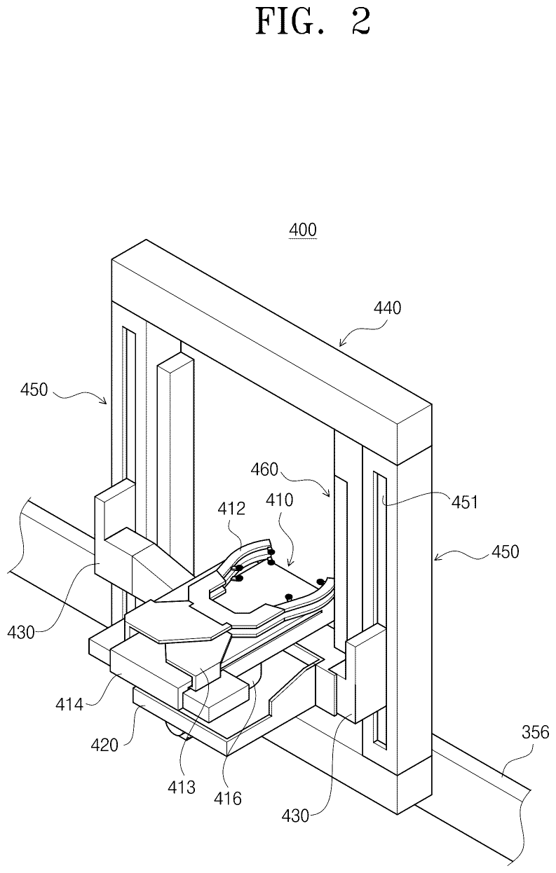

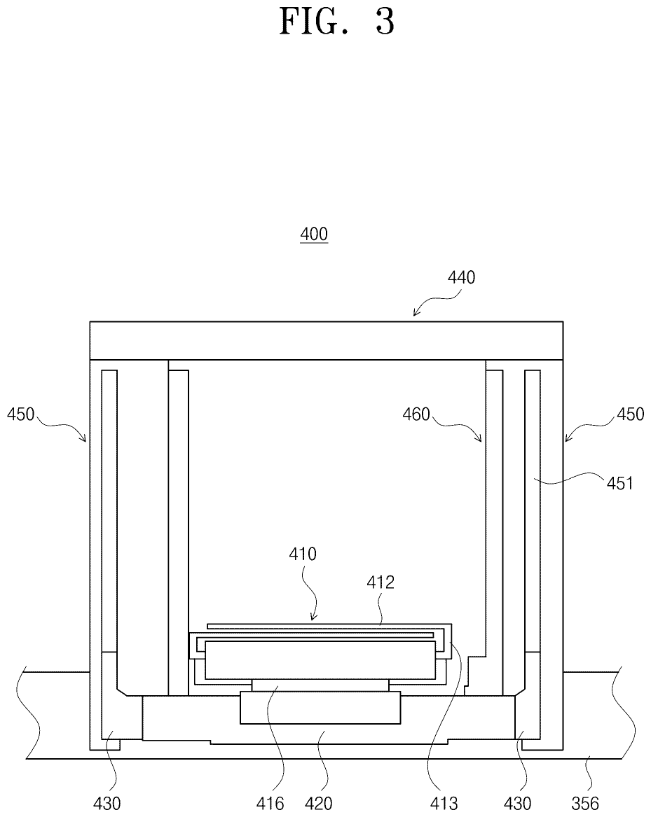

FIG. 2 is a perspective view showing an example of the substrate processing equipment of FIG. 1 and FIG. 3 is a front view of the substrate processing equipment shown in FIG. 2.

Hereafter, it is assumed in the following description that the substrate transfer equipment 400 is the substrate transfer equipment provided in the transfer chamber 350 of FIG. 1. However, unlike, the substrate transfer equipment 400 may be an index robot and, selectively, may be another robot provided in the substrate processing apparatus 10.

Referring to FIG. 2 and FIG. 3, the substrate transfer equipment 400 may include a robot body 410 and a moving frame 440.

The robot body 410 may include hands 412 that can operate forward and backward (in the direction X) while supporting substrates, a base 420, a hand actuating unit 414 that can rotate on the base 420, a mover 430.

The hand actuating unit 414 horizontally moves the hands 412 and the hands 412 are individually actuated by the hand actuating unit 414. The hand actuating unit 414 includes a connecting arm 413 connected with an actuator (not shown) therein and the hands 412 are installed at the end of the connecting arm 413. In this embodiment, the robot body 410 has two hands 412, but the number of the hands 412 may be changed, depending on the process condition. A rotating unit 416 that is a Z-axial actuator is installed under the hand actuating unit 414. The rotating unit 416 is coupled with the hand actuating unit 414 and rotates the hand actuating unit 414 around the vertical axis (Z-axis).

The robot body 410 may be supported on the base 420. The mover 430 is connected to both ends of the base 420. The mover 430 may be connected with a vertical actuating member 470 provided on a vertical frame.

The moving frame 440 may be provided in a type in which multiple frames are coupled to each other. For example, the moving frame 440 may include two vertical frames 450 spaced apart from each other. An exhaust duct 460 and a vertical actuating member 470 may be provided on the vertical frame 450.

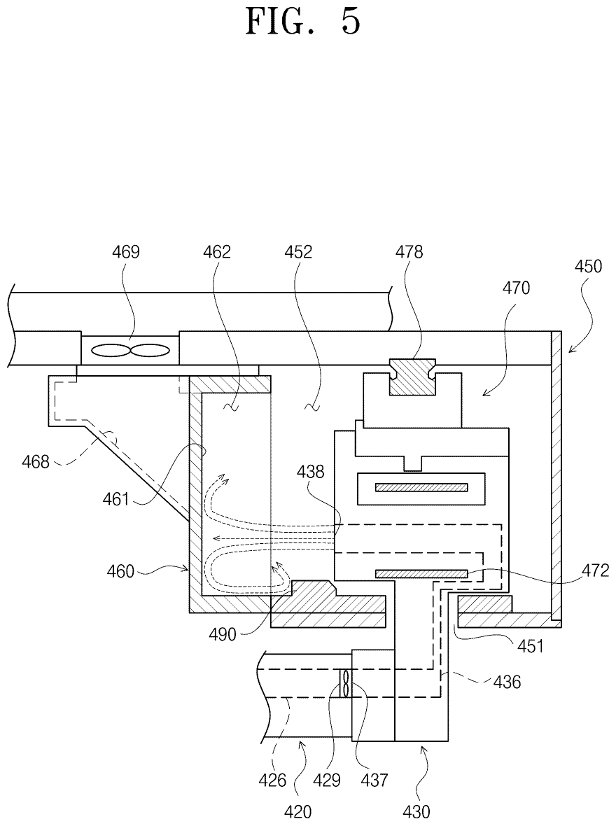

The robot body 410 is positioned between two vertical frames 450. The robot body 410 is connected to the vertical actuating members 470 (shown in FIG. 5) of the two vertical frames 450, so it can be vertically moved.

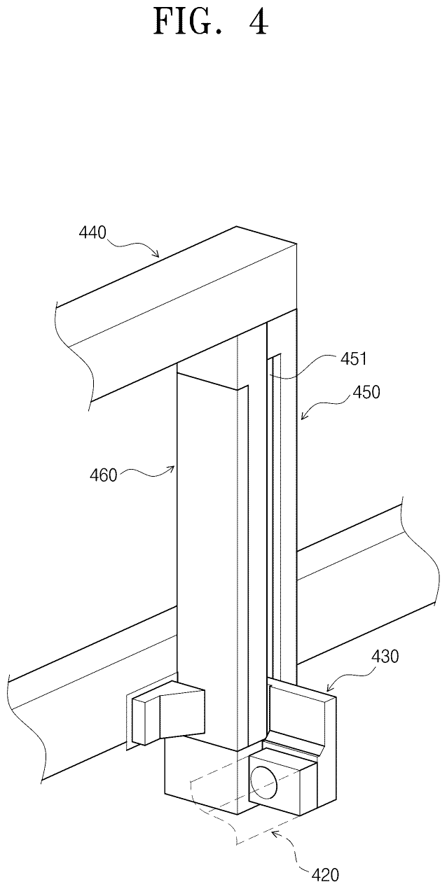

FIG. 4 is a perspective view showing main parts to describe the vertical frame and FIG. 5 is a horizontal cross-sectional view illustrating the inside of the vertical frame.

Referring to FIG. 2 to FIG. 5, the vertical frame 450 has a slit 451 formed in the longitudinal direction and provides a vertical space 452 therein. A first side of the vertical frame 450 may be provided in an open type. The exhaust duct 460 is mounted on the first side of the vertical frame 450. The exhaust duct 460 provides an exhaust space 462 connected with the vertical space 452. That is, the exhaust duct 460 is open on a first side toward the vertical space 452. The open first side of the vertical frame 450 is covered with the exhaust duct 460.

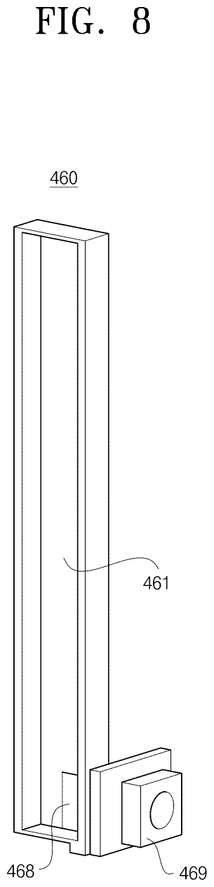

FIG. 8 is a view showing the exhaust duct. As in FIG. 8, the exhaust duct 460 has a second exhaust fan 469 for exhausting airflow in the exhaust space 462 to the outside. The second exhaust fan 469 is provided on the exhaust hole 468 formed at the lower end of the exhaust duct 460.

The vertical actuating member 470 is provided in the vertical space 452. The vertical actuating member 470 may be a kind of moving actuator for moving the robot body 410 in the direction Z. For example, the vertical actuating member 470 may be provided in a pulley-belt type for moving the robot body 410 in the up-down direction. Though not shown, the vertical actuating member 470 may include a driving pulley, a driven pulley, an actuating motor, a belt 472, and a vertical guide 478. Though not shown, the driving pulley and the driven pulley may be fixedly installed at the upper end and the lower end of the vertical frame 450.

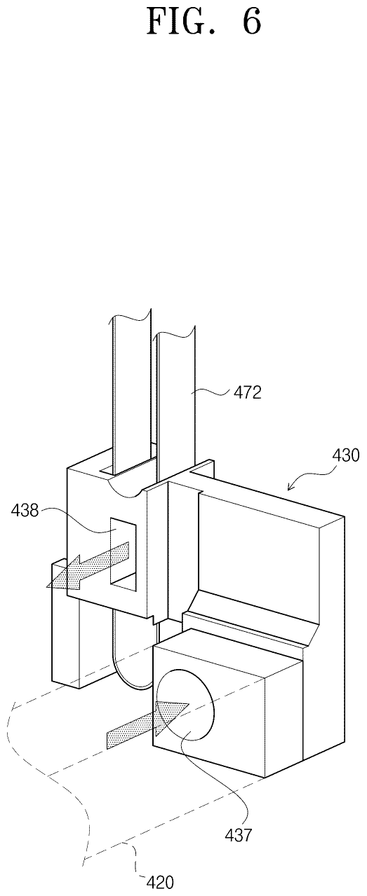

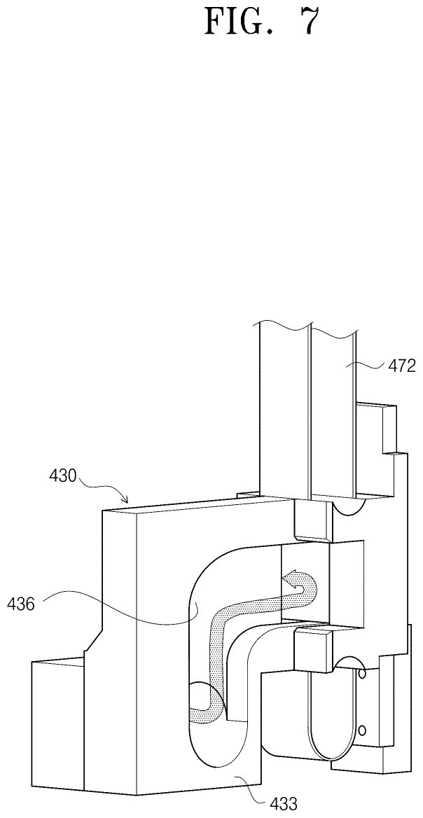

FIG. 6 and FIG. 7 are views illustrating the mover.

The mover 430 connected to both ends of the base 420 is coupled to the belt 472 by the actuating force of the actuating motor (not shown), thereby moving in the up-down direction. A first exhaust passage 426 for discharging particles produced in the process of actuating the robot body 410 to the outside may be provided at the base 420. The base 428 has a first exhaust fan 429. The first exhaust fan 429 is installed in the first exhaust passage 426 and generates airflows moving to the second exhaust passage 436 of the mover 430 from the first exhaust passage 426.

The mover 430 is connected to a first end of the base 420. The mover 430 can be coupled to the belt 472 and the vertical guide 478 of the vertical actuating member 470 through the slit 451. The mover 430 has the second exhaust passage 436. The second exhaust passage 436 is connected with the first exhaust passage 426 of the base 420. The inlet 437 of the second exhaust passage 436 is connected with the first exhaust passage 426 and the outlet 438 of the second exhaust passage 436 is provided to face a second side 461 that is opposite to the first open side of the exhaust duct 460. A cover (not shown) may be mounted on a first surface 433 of the mover 430 and the second exhaust passage formed on the first surface 433 of the mover 430 is provided by the cover.

As shown in FIG. 5, an airflow block member 490 may be provided in the vertical frame 450. The airflow block member 490 prevents airflow (particles) exhausted through the second exhaust passage 436 and colliding with the second side 461 of the exhaust duct 460 from leaking outside through the slit 451. For example, the airflow block member 490 may be provided in a projection type that protrudes from the inner surface of the vertical frame 450. The projection blocks airflow (particles) turning by colliding with the second side 461 of the exhaust duct 460, thereby being able to prevent the particles from leaking outside through the slit 451.

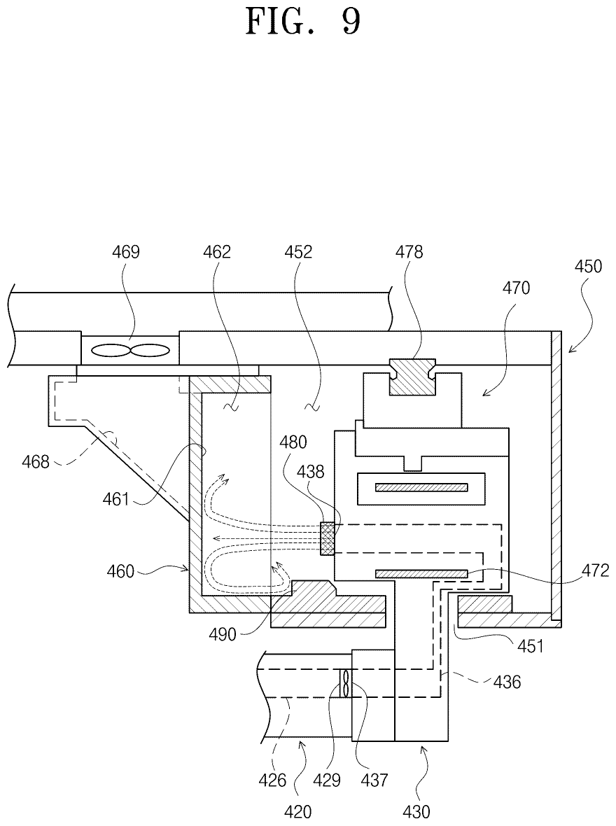

FIG. 9 is a view illustrating a modified example of the mover.

As in FIG. 9, the mover 430 may be provided with a momentum reduction member 480 for reducing the kinetic energy of particles that are discharged through the outlet 438 of the second exhaust passage 436. The momentum reduction member 480 may include a porous member or a porous member or a perforated plate. The particles that are discharged through the outlet 438 of the second exhaust passage 436 collide with the second side 461 of the exhaust duct 460 after the kinetic energy thereof is decreased by the momentum reduction member 480, so a vortex phenomenon in the exhaust space is minimized, whereby the particles can smoothly move in the exhaust space 462.

The substrate transfer equipment having the configuration described above can efficiently exhaust because the number of exhaust fans is minimized and particles produced by the transfer robot are smoothly discharged.

It should be understood that the above embodiments were proposed to help understand the present invention without limiting the scope of the present invention, and various modifications from the embodiments are also included in the scope of the present invention. The technological protection range of the present invention should be determined by the spirit of claims and it should be understood that the technological protection range of the present invention is not limited to the literal description of claims and the technological value thereof substantially reaches the equivalent range.

What is claimed is:

1. Substrate transfer equipment comprising:
a transfer robot transferring the substrate; and
a vertical actuating unit moving the transfer robot in an up-down direction,
the vertical actuating unit comprises:
a vertical frame having a slit formed with a longitudinal direction thereof provided in the up-down direction, and having a vertical space formed therein;
an exhaust duct having an exhaust space connected with the vertical space and provided on a side of the vertical frame; and
an actuating member positioned in the vertical space and moving a supporting unit in the up-down direction,
wherein the exhaust duct is provided such that a first side is open toward the vertical space.

2. The substrate transfer equipment of claim 1, wherein the transfer robot comprises:
a robot body having handles supporting the substrate;
a base supporting the robot body, having a Z-axial actuating unit rotating the robot body about a vertical axis, and having a first exhaust passage for discharging particles produced in a process of actuating the robot body to the outside; and
a mover connected to a first end of the base, coupled to the actuating member through the slit, and having a second exhaust passage connected with the first exhaust passage.

3. The substrate transfer equipment of claim 2, wherein the base further comprises a first exhaust fan installed in the first exhaust passage to generate airflow moving from the first exhaust passage to the second exhaust passage.

4. The substrate transfer equipment of claim 2, wherein the mover is configured such that an outlet of the second exhaust passage faces a second side that is opposite to the open first side of the exhaust duct.

5. The substrate transfer equipment of claim 4, wherein the mover further comprises a momentum reduction member provided to reduce momentum of particles that are discharged through the outlet of the second exhaust passage.

6. The substrate transfer equipment of claim 5, wherein the momentum reduction member comprises a porous member or a perforated plate.

7. The substrate transfer equipment of claim 4, wherein the vertical frame further comprises an airflow block member preventing airflow, which is exhausted through the second exhaust passage and collides with the second side of the exhaust duct, from leaking to the outside through the slit.

8. The substrate transfer equipment of claim 7, wherein the airflow block member comprises a projection protruding from an inner surface of the vertical frame.

9. The substrate transfer equipment of claim 2, wherein the exhaust duct further comprises a second exhaust fan exhausting airflow in the exhaust space to the outside.

10. A substrate processing apparatus for processing a substrate, comprising:
a process chamber processing the substrate; and
a transfer chamber provided adjacent to the process chamber and having a substrate transfer equipment transferring the substrate to the process chamber,
wherein the transfer chamber comprises:
a transfer robot transferring the substrate; and
a pair of vertical actuating units configured to horizontally move along a guide rail, supporting the transfer robot on both sides, and moving the transfer robot in an up-down direction,
wherein the vertical actuating unit comprises:
a vertical frame having a slit formed with a longitudinal direction thereof provided in the up-down direction, and having a vertical space formed therein;
an exhaust duct having an exhaust space connected with the vertical space and provided on a side of the vertical frame; and
an actuating member positioned in the vertical space and moving a supporting unit in the up-down direction,
wherein the exhaust duct is provided such that a first side is open toward the vertical space.

11. The substrate processing apparatus of claim 10, wherein the transfer robot comprises:
a robot body having handles supporting the substrate;
a base supporting the robot body, having a Z-axial actuating unit rotating the robot body about a vertical axis, and having a first exhaust passage for discharging particles produced in a process of actuating the robot body to the outside; and
a mover connected to a first end of the base, coupled to the actuating member through the slit, and having a second exhaust passage connected with the first exhaust passage.

12. The substrate processing apparatus of claim 11, wherein the base further comprises a first exhaust fan installed in the first exhaust passage to generate airflow moving from the first exhaust passage to the second exhaust passage.

13. The substrate processing apparatus of claim 11, wherein the mover is configured such that an outlet of the second exhaust passage faces a second side that is opposite to the open first side of the exhaust duct.

14. The substrate processing apparatus of claim 13, wherein the mover further comprises a momentum reduction member provided to reduce momentum of particles that are discharged through the outlet of the second exhaust passage.

15. The substrate processing apparatus of claim 14, wherein the momentum reduction member comprises a porous member or a perforated plate.

16. The substrate processing apparatus of claim 13, wherein the vertical frame further comprises an airflow block member preventing airflow, which is exhausted through the second exhaust passage and collides with the second side of the exhaust duct, from leaking to the outside through the slit.

17. The substrate processing apparatus of claim 16, wherein the airflow block member comprises a projection protruding from an inner surface of the vertical frame.

18. The substrate processing apparatus of claim 13, wherein the exhaust duct further comprises a second exhaust fan exhausting airflow in the exhaust space to the outside.

19. Substrate transfer equipment comprising:
a transfer robot transferring the substrate; and
a vertical actuating unit moving the transfer robot in an up-down direction,
wherein the vertical actuating unit comprises:
a vertical frame having a slit formed with a longitudinal direction thereof provided in the up-down direction, and having a vertical space formed therein;
an exhaust duct having an exhaust space connected with the vertical space, provided on a side of the vertical frame, and being open on a first side being in contact with the vertical space; and
an actuating member positioned in the vertical space and moving a supporting unit in the up-down direction,
wherein the transfer robot comprises:
a robot body having handles supporting a substrate;
a base supporting the robot body, having a Z-axial actuating unit rotating the robot body about a vertical axis, and having a first exhaust passage for discharging particles produced in a process of actuating the robot body to the outside;
a mover connected to a first end of the base, coupled to the actuating member through the slit, and having a second exhaust passage connected with the first exhaust passage; and
a first exhaust fan installed in the first exhaust passage and providing airflow moving from the first exhaust passage to the second exhaust passage,
wherein the mover is configured such that an outlet of the second exhaust passage faces a second side that is opposite to the open first side of the exhaust duct and comprises a momentum reduction member provided to reduce momentum of particles that are discharged through the outlet of the second exhaust passage,
wherein the vertical frame comprises an airflow block member preventing airflow, which is exhausted through the second exhaust passage and collides with the second side of the exhaust duct, from leaking to the outside through the slit.

20. The substrate transfer equipment of claim 19, wherein the momentum reduction member comprises a porous member or a perforated plate,
the airflow block member comprises a projection protruding from an inner surface of the vertical frame, and
the exhaust duct further comprises a second exhaust fan exhausting airflow in the exhaust space to the outside.
